(19) United States
(12) Patent Application Publication
(10) Pub. No.: US 2022/0262839 A1
(43) Pub. Date: Aug. 18, 2022

(54) SOLID-STATE IMAGING DEVICE AND ELECTRONIC DEVICE

(71) Applicant: SONY SEMICONDUCTOR SOLUTIONS CORPORATION, KANAGAWA (JP)

(72) Inventors: MASAHIKO YUKAWA, TOKYO (JP); SHOGO ONO, KANAGAWA (JP)

(21) Appl. No.: 17/597,372

(22) PCT Filed: Jun. 5, 2020
(86) PCT No.: PCT/JP2020/022281

§ 371 Date: Jan. 4, 2022

(30) Foreign Application Priority Data
Jul. 17, 2019 (JP) 2019-132269

(51) Int. Cl. H01L 27/146

(52) U.S. Cl. CPC H01L 27/14623; H01L 27/14636

(57) ABSTRACT

To suppress image quality degradation. A solid-state imaging device according to an embodiment includes: a semiconductor substrate (131) including a light receiving element in a first region on a first surface; a glass substrate (133) facing the first surface of the semiconductor substrate; a resin layer (132) that supports the glass substrate against the first surface; and a layer (134) provided in the glass substrate, the layer being provided in a third region corresponding to a second region surrounding the first region of the semiconductor substrate in a substrate thickness direction of the semiconductor substrate, the layer having a physical property with respect to visible light different from a physical property of the glass substrate.

### FIELD

The present disclosure relates to a solid-state imaging device and an electronic device.

### BACKGROUND

In recent years, electronic devices such as a mobile terminal device with a camera, and a digital still camera have been experiencing an advancement in cameras which have achieved higher resolution, further miniaturized and thinner bodies. A typical method of miniaturization and thinning is to form a solid-state imaging device into a chip size package (CSP) type device.

### CITATION LIST

### Patent Literature

Patent Literature 1: JP 2007-142058 A

Patent Literature 2: JP 2010-40672 A

### SUMMARY

### Technical Problem

However, the miniaturization of the solid-state imaging device causes a problem that, when a side surface (hereinafter, referred to as an end surface) of a glass substrate that protects a light receiving surface of the solid-state imaging device approaches an element formation region of the solid-state imaging device, light that has entered from an end surface of the glass substrate is incident on the light receiving region of the solid-state imaging device, resulting in a flare phenomenon (hereinafter, referred to as glass end surface flare) that impairs sharpness in all or part of an image, leading to image quality degradation.

In view of this, the present disclosure proposes a solid-state imaging device and an electronic device capable of suppressing image quality degradation.

### Solution to Problem

To solve the above-described problem, a solid-state imaging device according to one aspect of the present disclosure comprises: a semiconductor substrate including a light receiving element in a first region on a first surface; a glass substrate facing the first surface of the semiconductor substrate; a resin layer that supports the glass substrate against the first surface; and a layer provided in the glass substrate, the layer being provided in a third region corresponding to a second region surrounding the first region of the semiconductor substrate in a substrate thickness direction of the semiconductor substrate, the layer having a physical property with respect to visible light different from a physical property of the glass substrate.

### BRIEF DESCRIPTION OF DRAWINGS

FIG. 1 is a block diagram illustrating a schematic configuration example of an electronic device equipped with a solid-state imaging device according to a first embodiment.

FIG. 2 is a block diagram illustrating a schematic configuration example of a solid-state imaging device according to the first embodiment.

FIG. 3 is a circuit diagram illustrating a schematic configuration example of a unit pixel according to the first embodiment.

FIG. 4 is a diagram illustrating a stacked structure example of the solid-state imaging device according to the first embodiment.

FIG. 5 is a cross-sectional view illustrating a cross-sectional structure example of an image sensor according to the first embodiment.

FIG. 6 is a perspective view illustrating glass end surface flare occurring in the image sensor having no light shielding layer according to the first embodiment.

FIG. 7 is a perspective view of an image sensor having a light shielding layer according to the first embodiment.

FIG. 8 is an enlarged view obtained by enlarging one corner portion of the image sensor according to the first embodiment.

FIG. 9 is a process cross-sectional view (part 1) illustrating an example of a method of manufacturing the image sensor according to the first embodiment.

FIG. 10 is a process cross-sectional view (part 2) illustrating an example of a method of manufacturing the image sensor according to the first embodiment.

FIG. 11 is a process cross-sectional view (part 3) illustrating an example of a method of manufacturing the image sensor according to the first embodiment.

FIG. 12 is a process cross-sectional view (part 4) illustrating an example of a method of manufacturing the image sensor according to the first embodiment.

FIG. 13 is an enlarged view obtained by enlarging one corner portion of the image sensor according to a second embodiment.

FIG. 14 is an enlarged view obtained by enlarging one corner portion of the image sensor according to a third embodiment.

FIG. 15 is an enlarged view obtained by enlarging one corner portion of the image sensor according to a fourth embodiment.

FIG. 16 is a perspective view of an image sensor including a light shielding layer according to a fifth embodiment.

FIG. 17 is a cross-sectional view illustrating a cross-sectional structure example of an image sensor according to a sixth embodiment.

FIG. 18 is a cross-sectional view illustrating a cross-sectional structure example of an image sensor according to a seventh embodiment.

FIG. 19 is a cross-sectional view illustrating a cross-sectional structure example of an image sensor according to a first example of an eighth embodiment.

FIG. 20 is a cross-sectional view illustrating a cross-sectional structure example of an image sensor according to a second example of the eighth embodiment.

FIG. 21 is a cross-sectional view illustrating a cross-sectional structure example of an image sensor according to a first example of a ninth embodiment.

FIG. 22 is a cross-sectional view illustrating a cross-sectional structure example of an image sensor according to a second example of the ninth embodiment.

FIG. 23 is a process cross-sectional view illustrating an example of a method of manufacturing an image sensor according to a tenth embodiment.

FIG. 24 is a cross-sectional view illustrating a cross-sectional structure example of an image sensor according to the tenth embodiment.

FIG. 25 is a cross-sectional view in a case where the inclination angle of the light shielding layer is minimized in the specific example of the tenth embodiment.

FIG. 26 is a cross-sectional view in a case where an inclination angle of a light shielding layer is maximized in a specific example of the tenth embodiment.

FIG. 27 is a block diagram illustrating an example of a schematic configuration of a vehicle control system.

FIG. 28 is a diagram illustrating an example of installation positions of a vehicle exterior information detector and an imaging unit.

### DESCRIPTION OF EMBODIMENTS

An embodiment of the present disclosure will be described below in detail with reference to the drawings. In each of the following embodiments, the same parts are denoted by the same reference symbols, and a repetitive description thereof will be omitted.

The present disclosure will be described in the following order.

1. First Embodiment

1.1 Configuration example of electronic device

1.2 Configuration example of solid-state imaging device

1.3 Configuration example of unit pixel

1.4 Example of basic functions of unit pixel

1.5 Stacked structure example of solid-state imaging device

1.6 Cross-sectional structure example

1.7 Suppression of glass end surface flare

1.8 Light shielding layer

1.9 Manufacturing method

1.10 Action/effects

2. Second Embodiment

3. Third Embodiment

4. Fourth Embodiment

5. Fifth Embodiment

6. Sixth Embodiment

7. Seventh Embodiment

8. Eighth Embodiment

8.1 First example

8.2 Second example

8.3 Action/effects

9. Ninth Embodiment

9.1 First example

9.2 Second example

9.3 Action/effects

10. Tenth Embodiment

11. Example of application to moving object

### 1. First Embodiment

First, a solid-state imaging device and an electronic device according to a first embodiment will be described in detail with reference to the drawings.

1.1 Configuration Example of Electronic Device

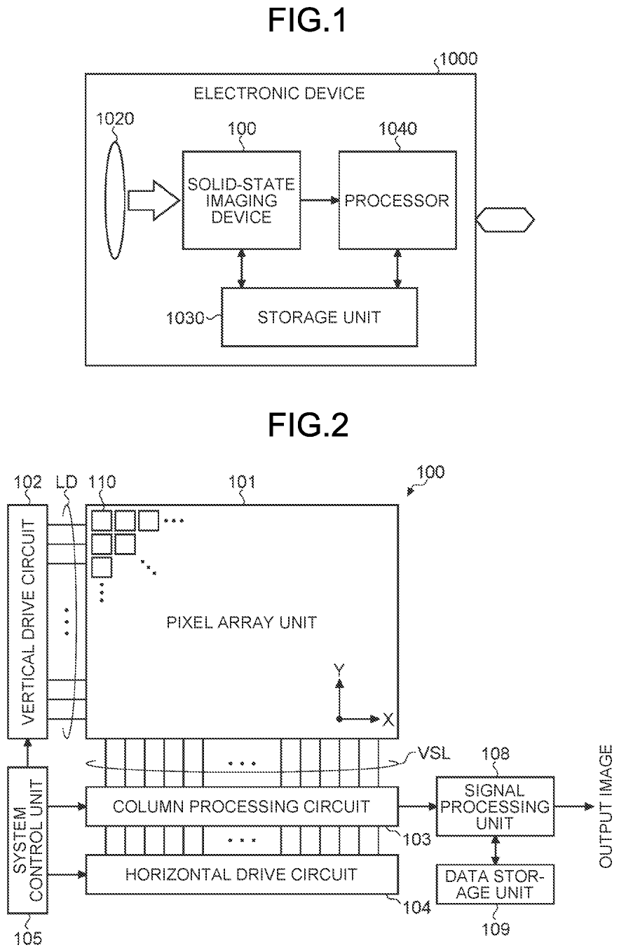

FIG. 1 is a block diagram illustrating a schematic configuration example of an electronic device equipped with a solid-state imaging device according to a first embodiment. As illustrated in FIG. 1, an electronic device 1000 includes an imaging lens 1020, a solid-state imaging device 100, a storage unit 1030, and a processor 1040, for example.

The imaging lens 1020 is an example of an optical system that collects incident light and forms an optical image based on the light on a light receiving surface of the solid-state imaging device 100. The light receiving surface may be a surface on which photoelectric conversion elements are arranged in the solid-state imaging device 100. The solid-state imaging device 100 photoelectrically converts incident light to generate image data. Furthermore, the solid-state imaging device 100 executes predetermined signal processing such as noise removal and white balance adjustment on the generated image data.

The storage unit 1030 includes, for example, a flash drive, dynamic random access memory (DRAM), static random access memory (SRAM), or the like, and records image data or the like input from the solid-state imaging device 100.

The processor 1040 is constituted by using, for example, a central processing unit (CPU) or the like, and may include an application processor that executes an operating system, various types of application software, or the like, a graphics processing unit (GPU), a baseband processor, and the like. The processor 1040 executes various processes as necessary on the image data input from the solid-state imaging device 100, the image data read out from the storage unit 1030, and the like, executes display to the user, and transmits the image data to the outside via a predetermined network.

1.2 Configuration Example of Solid-State Imaging Device

FIG. 2 is a block diagram illustrating a schematic configuration example of a complementary metal-oxide-semiconductor (CMOS) solid-state imaging device (hereinafter, simply referred to as an image sensor) according to the first embodiment. Here, the CMOS image sensor is an image sensor created by applying or partially using a CMOS process. The image sensor 100 according to the first embodiment may be a back-illuminated sensor having an incident surface on a side opposite to the element formation surface in the semiconductor substrate (hereinafter, referred to as a back surface), or may be a front-illuminated sensor having an incident surface on its front surface side.

As illustrated in FIG. 2, the image sensor 100 includes a pixel array unit 101, a vertical drive circuit 102, a column processing circuit 103, a horizontal drive circuit 104, a system control unit 105, a signal processing unit 108, and a data storage unit 109, for example. In the following description, the vertical drive circuit 102, the column processing circuit 103, the horizontal drive circuit 104, the system control unit 105, the signal processing unit 108, and the data storage unit 109 are collectively referred to as peripheral circuits.

The pixel array unit 101 has a configuration in which unit pixels (hereinafter, simply described as “pixels” in some cases) 110 each having a photoelectric conversion element that generates and accumulates a charge according to the amount of received light are arranged in a row direction and a column direction, that is, in a two-dimensional grid-like matrix pattern (hereinafter, referred to as a matrix). Here, the row direction refers to a pixel arrangement direction in a pixel row (lateral direction in drawings), and the column direction refers to a pixel arrangement direction in a pixel column (vertical direction in drawings). Specific circuit configurations and pixel structures of the unit pixels will be described below in detail.

The pixel array unit 101 has pixel drive lines LD wired in the row direction for individual pixel rows while having vertical signal lines VSL wired in the column direction for individual pixel columns with regard to the pixel array in a matrix. The pixel drive line LD transmits a drive signal for conduct drive when a signal is read out from a pixel. Although FIG. 2 is a case where the pixel drive lines LD are illustrated as one-to-one wiring patterns, wiring patterns are not limited to this. One end of the pixel drive line LD is connected to an output terminal corresponding to each of rows of the vertical drive circuit 102.

The vertical drive circuit 102 includes a shift register, an address decoder, and the like, and drives all the pixels of the pixel array unit 101 simultaneously or row by row. That is, together with the system control unit 105 that controls the vertical drive circuit 102, the vertical drive circuit 102 constitutes a drive unit that controls the operation of each of pixels of the pixel array unit 101. Although a specific configuration of the vertical drive circuit 102 is not illustrated, the vertical drive circuit typically includes two scan systems of a read-out scan system and a sweep-out scan system.

In order to read out a signal from the unit pixel, the read-out scan system sequentially performs selective scan of unit pixels of the pixel array unit 101 row by row. The signal read out from the unit pixel is an analog signal. The sweep-out scan system performs sweep-out scan on a read out row on which read-out scan is to be performed by the read-out scan system, prior to the read-out scan by an exposure time.

By the sweep-out scan by the sweep-out scan system, unnecessary charges are swept out from the photoelectric conversion element of the unit pixel of the read-out target row, and the photoelectric conversion element is reset. By sweeping out (resetting) unnecessary charges in the sweep-out scan system, an electronic shutter operation is performed. Here, the electronic shutter operation refers to an operation of discarding charges of the photoelectric conversion element and newly starting exposure (starting accumulation of charges).

The signal read out by the read-out operation by the read-out scan system corresponds to the amount of light received after the immediately preceding read-out operation or electronic shutter operation. Subsequently, a period from the read-out timing by the immediately preceding read-out operation or the sweep-out timing of the electronic shutter operation to the read-out timing of the current read-out operation corresponds to a charge accumulation period (also referred to as an exposure period) in the unit pixel.

A signal output from each of unit pixels in the pixel row selectively scanned by the vertical drive circuit 102 is input to the column processing circuit 103 through each of the vertical signal lines VSL for each pixel column. The column processing circuit 103 performs predetermined signal processing on the signal output from each pixel of the selected row through the vertical signal line VSL for each of the pixel columns of the pixel array unit 101, and temporarily holds the pixel signal after the signal processing.

Specifically, the column processing circuit 103 performs at least a noise removal process, for example, a correlated double sampling (CDS) process or a double data sampling (DDS) process, as the signal processing. For example, the CDS process removes the fixed pattern noise unique to the pixel such as the reset noise and the threshold variation of the amplification transistor in the pixel. The column processing circuit 103 also has an analog-digital (AD) conversion function, for example, and converts an analog pixel signal obtained by reading out from the photoelectric conversion element into a digital signal, and outputs the digital signal.

The horizontal drive circuit 104 includes a shift register, an address decoder, and the like, and sequentially selects a read-out circuit (hereinafter, referred to as a pixel circuit) corresponding to a pixel column of the column processing circuit 103. By the selective scan performed by the horizontal drive circuit 104, pixel signals subjected to signal processing for each pixel circuit in the column processing circuit 103 are sequentially output.

The system control unit 105 includes a timing generator that generates various timing signals and the like, and performs drive control of the vertical drive circuit 102, the column processing circuit 103, the horizontal drive circuit 104, and the like based on various timings generated by the timing generator.

The signal processing unit 108 has at least an arithmetic processing function, and performs various signal processing such as arithmetic processing on the pixel signal output from the column processing circuit 103. The data storage unit 109 temporarily stores data necessary for processes at signal processing in the signal processing unit 108.

Note that the image data output from the signal processing unit 108 may be subjected to predetermined processing in the processor 1040 or the like in the electronic device 1000 equipped with the image sensor 100, or may be transmitted to the outside via a predetermined network, for example.

1.3 Configuration Example of Unit Pixel

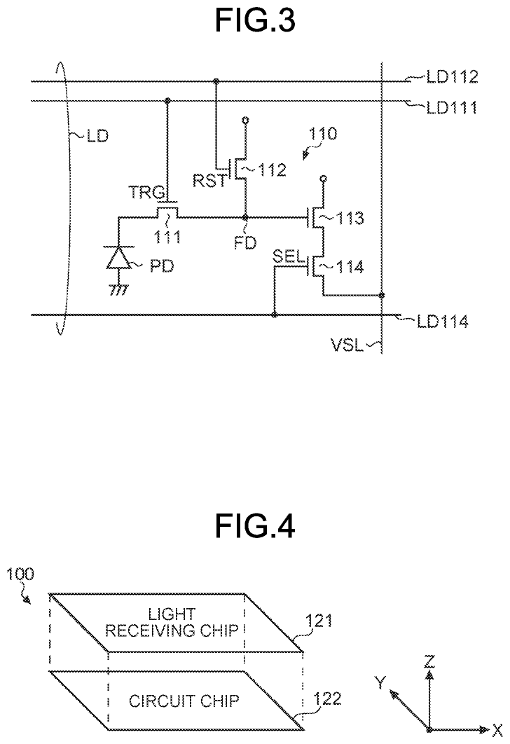

FIG. 3 is a circuit diagram illustrating a schematic configuration example of a unit pixel according to the first embodiment. As illustrated in FIG. 3, the unit pixel 110 includes a photodiode PD, a transfer transistor 111, a reset transistor 112, an amplification transistor 113, a selection transistor 114, and a floating diffusion layer FD.

The gate of the selection transistor 114 is connected to a selection transistor drive line LD114 included in the pixel drive line LD, the gate of the reset transistor 112 is connected to a reset transistor drive line LD112 included in the pixel drive line LD, and the gate of the transfer transistor 111 is connected to a transfer transistor drive line LD111 included in the pixel drive line LD. Furthermore, the drain of the amplification transistor 113 is connected to the vertical signal line VSL having one end connected to the column processing circuit 103, via the selection transistor 114.

In the following description, the reset transistor 112, the amplification transistor 113, and the selection transistor 114 are also collectively referred to as a pixel circuit. The pixel circuit may include the floating diffusion layer FD and/or the transfer transistor 111.

The photodiode PD may be a light receiving element that photoelectrically converts incident light. The transfer transistor 111 transfers the charge generated in the photodiode PD. The floating diffusion layer FD accumulates the charge transferred by the transfer transistor 111. The amplification transistor 113 causes a pixel signal having a voltage value corresponding to the charge accumulated in the floating diffusion layer FD to emerge in the vertical signal line VSL. The reset transistor 112 releases the charge accumulated in the floating diffusion layer FD. The selection transistor 114 selects the unit pixel 110 as a read-out target.

The photodiode PD has its anode grounded and its cathode connected to the source of the transfer transistor 111. The drain of the transfer transistor 111 is connected to the source of the reset transistor 112 and the gate of the amplification transistor 113, and a node which is a connection point of these transistors constitutes the floating diffusion layer FD. The drain of the reset transistor 112 is connected to a vertical reset input line (not illustrated).

The source of the amplification transistor 113 is connected to a vertical current supply line (not illustrated). The drain of the amplification transistor 113 is connected to the source of the selection transistor 114, while the drain of the selection transistor 114 is connected to the vertical signal line VSL.

The floating diffusion layer FD converts the accumulated charge into a voltage of a voltage value corresponding to the charge amount. The floating diffusion layer FD may be an earth capacitance, for example. However, the configuration is not limited thereto, and the floating diffusion layer FD may be a capacitance added by intentionally connecting a capacitor or the like to a node which connects the drain of the transfer transistor 111, the source of the reset transistor 112, and the gate of the amplification transistor 113 to each other.

1.4 Example of Basic Functions of Unit Pixel

Next, basic functions of the unit pixel 110 will be described with reference to FIG. 3. The reset transistor 112 controls discharge (reset) of the charge accumulated in the floating diffusion layer FD in accordance with a reset signal RST supplied from the vertical drive circuit 102 via the reset transistor drive line LD112. Incidentally, by turning on the transfer transistor 111 when the reset transistor 112 is in an on state, it is also possible to discharge (reset) the charge accumulated in the photodiode PD in addition to the charge accumulated in the floating diffusion layer FD.

When a reset signal RST at a high level is input to the gate of the reset transistor 112, the floating diffusion layer FD is clamped to a voltage applied through the vertical reset input line. With this operation, the charges accumulated in the floating diffusion layer FD are discharged (reset).

Furthermore, when the reset signal RST at a low level is input to the gate of the reset transistor 112, the floating diffusion layer FD is electrically disconnected from the vertical reset input line and comes into a floating state.

The photodiode PD photoelectrically converts incident light and generates a charge corresponding to the amount of light. The generated charge is accumulated on the cathode side of the photodiode PD. The transfer transistor 111 controls transfer of charges from the photodiode PD to the floating diffusion layer FD in accordance with a transfer control signal TRG supplied from the vertical drive circuit 102 via the transfer transistor drive line LD111.

For example, when the transfer control signal TRG at the high level is input to the gate of the transfer transistor 111, the charge accumulated in the photodiode PD is transferred to the floating diffusion layer FD. On the other hand, when the transfer control signal TRG at the low level is supplied to the gate of the transfer transistor 111, the transfer of the charge from the photodiode PD is stopped.

As described above, the floating diffusion layer FD has a function of converting the charge transferred from the photodiode PD via the transfer transistor 111 into a voltage having a voltage value corresponding to the charge amount. Therefore, in the floating state in which the reset transistor 112 is turned off, the potential of the floating diffusion layer FD is modulated in accordance with charge amounts individually accumulated.

The amplification transistor 113 functions as an amplifier using a potential fluctuation of the floating diffusion layer FD connected to the gate of the amplification transistor 113 as an input signal, and an output voltage signal from the transistor 113 emerges as a pixel signal in the vertical signal line VSL via the selection transistor 114.

The selection transistor 114 controls the emergence of the pixel signal by the amplification transistor 113 in the vertical signal line VSL in accordance with a selection control signal SEL supplied from the vertical drive circuit 102 via the selection transistor drive line LD114. For example, when the selection control signal SEL at the high level is input to the gate of the selection transistor 114, a pixel signal by the amplification transistor 113 emerges in the vertical signal line VSL. In contrast, when the selection control signal SEL at the low level is input to the gate of the selection transistor 114, the emergence of the pixel signal in the vertical signal line VSL is stopped. This makes it possible to extract only the output of the selected unit pixel 110 in the vertical signal line VSL connect to the plurality of unit pixels 110.

1.5 Stacked Structure Example of Solid-State Imaging Device

FIG. 4 is a diagram illustrating a stacked structure example of the image sensor according to the first embodiment. As illustrated in FIG. 4, the image sensor 100 has a stack structure in which a light receiving chip 121 and a circuit chip 122 are vertically stacked. The light receiving chip 121 is, for example, a semiconductor chip including a pixel array unit 101 having arrays of photodiodes PD, and the circuit chip 122 is, for example, a semiconductor chip including a pixel circuit illustrated in FIG. 3, a peripheral circuit in FIG. 2, and the like.

For example, the light receiving chip 121 and the circuit chip 122 can be bonded to each other by using direct bonding in which the bonding surfaces of the chips are flattened and then the chips are bonded to each other by an electronic force. However, the bonding method is not limited thereto, and for example, it is also allowable to use other bonding methods such as Cu—Cu bonding in which copper (Cu) electrode pads formed on the bonding surfaces are bonded to each other, or bump bonding.

In addition, the light receiving chip 121 and the circuit chip 122 are electrically connected via a connection portion such as a through-silicon via (TSV) penetrating the semiconductor substrate, for example. The connection using the TSV is implemented by adopting a method such as a twin TSV method in which two TSVs, that is, a TSV provided in the light receiving chip 121 and a TSV provided from the light receiving chip 121 to the circuit chip 122 are connected to each other on an outer surface of the chip, or a shared TSV method in which both chips are connected by a TSV penetrating from the light receiving chip 121 to the circuit chip 122, for example.

Note that, in a case where the light receiving chip 121 and the circuit chip 122 are bonded to each other by using Cu—Cu bonding or bump bonding, the chips are electrically connected via a Cu—Cu bonding portion or a bump bonding portion.

1.6 Cross-Sectional Structure Example

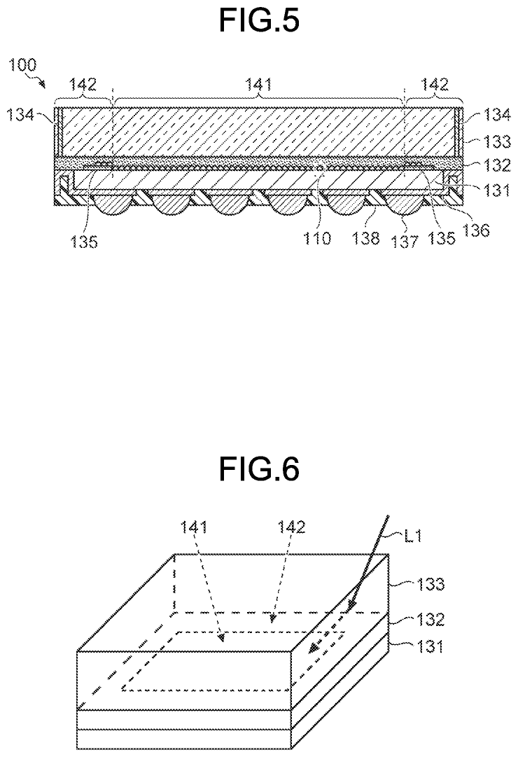

FIG. 5 is a cross-sectional view illustrating a cross-sectional structure example of an image sensor according to the first embodiment. Although the present description is an exemplary case where the image sensor 100 is a back-illuminated type, the image sensor may be a front-illuminated type as described above.

As illustrated in FIG. 5, the image sensor 100 includes a semiconductor substrate 131 provided with a plurality of unit pixels 110 and a peripheral circuit. The semiconductor substrate 131 may be, for example, a semiconductor substrate having a stacked structure in which the light receiving chip 121 and the circuit chip 122 in FIG. 4 are vertically stacked.

The plurality of unit pixels 110 is arranged in a matrix pattern on the back surface side (upper surface side in the drawing; also referred to as or a first surface) of the semiconductor substrate 131, for example. Among the unit pixels 110 arranged in a matrix, the photodiodes PD of the unit pixels 110 located at the peripheral edge are shielded by, for example, a light shielding film (also referred to as an optical black (OPB) film) 135 that shields light of a specific wavelength band such as visible light.

Each of the unit pixels 110 may include an on-chip lens arranged on the back surface of the semiconductor substrate 131. For example, the on-chip lens may be provided for each of photodiodes PD arranged on the back surface side of the semiconductor substrate 131.

In the following description, a region including an array of the unit pixels 110 in which the photodiodes PD are not covered with an OPB film 135 is defined as an effective pixel region (also referred to as a first region) 141, while a region including an array of the unit pixels 110 in which the photodiodes PD are covered with the OPB film 135 is defined as a light shielding region. Furthermore, a region on the back surface of the semiconductor substrate 131 between the side surface of the image sensor 100 and the effective pixel region 141 is defined as a peripheral region (also referred to as a second region) 142. In this case, the light shielding region covered with the OPB film 135 is included in the peripheral region 142. Note that the effective pixel region 141 may be a rectangular region including an array of the unit pixels 110 used to generate image data.

On the back surface side (upper surface side in the drawing) of the semiconductor substrate 131, there are provided a resin layer 132 and a glass substrate 133. Furthermore, on the front surface side (lower surface side in the drawing) of the semiconductor substrate 131, there are provided an electrode pad 136, a ball bump 137, and passivation film 138.

The glass substrate 133 is, for example, a member for protecting the back surface (corresponding to the light receiving surface) of the semiconductor substrate 131 and maintaining the physical strength of the image sensor 100.

The resin layer 132 is, for example, an optically transparent epoxy resin, low melting point glass, ultraviolet curable resin, or the like, and may be an adhesive for bonding the glass substrate 133 and the semiconductor substrate 131 to each other. The resin layer 132 may cover the unit pixel 110 in the effective pixel region 141, for example.

Although not illustrated in FIG. 5, it is also allowable to provide, on the bonding surface between the light receiving chip 121 and the circuit chip 122 in the semiconductor substrate 131, a wiring layer formed of an insulating film and including wiring for connecting the unit pixel 110 and a peripheral circuit to each other. In this case, for example, a silicon oxide film (SiO₂), a silicon nitride film (SiN), or the like can be used for the insulating film of the wiring layer.

The passivation film 138 is, for example, a film formed by using photosensitive polyimide, polybenzoxazole (PBC)), a silicone-based resin material, or the like, and has a role of protecting the front surface side of the semiconductor substrate 131, the electrode pad 136, and the like.

The electrode pad 136 is formed by using a conductive material such as metal, for example, and is electrically connected to a peripheral circuit and the like provided on the semiconductor substrate 131.

The ball bump 137 is, for example, a solder ball or the like provided at an exposed portion of the electrode pad 136, and is an external terminal for electrically connecting the image sensor 100 to a circuit board and the like. The structure of the external terminal is not limited to the structure using the ball bump 137, and it is also possible to adopt a structure such as a flat pad.

In the present embodiment, in a region (referred to as a third region) corresponding to the peripheral region 142 of the semiconductor substrate 131 in the substrate thickness direction of the semiconductor substrate 131 (hereinafter, referred to as an up-down direction, which will be used for description in the following), which is a region in the vicinity of an end surface of the glass substrate 133 (for example, the region closer to the end surface of the glass substrate 133 than to the effective pixel region 141), there is provided, along the end surface of the glass substrate 133, a layer (hereinafter, referred to as a light shielding layer) 134 having a physical property with respect to visible light different from the physical property of an unprocessed region (hereinafter, referred to as bare glass) in the glass substrate 133. Note that the physical properties in the present description may be physical properties related to light transmission, such as transmittance (which may be transparency), reflectance, and refractive index with respect to visible light.

1.7 Suppression of Glass End Surface Flare

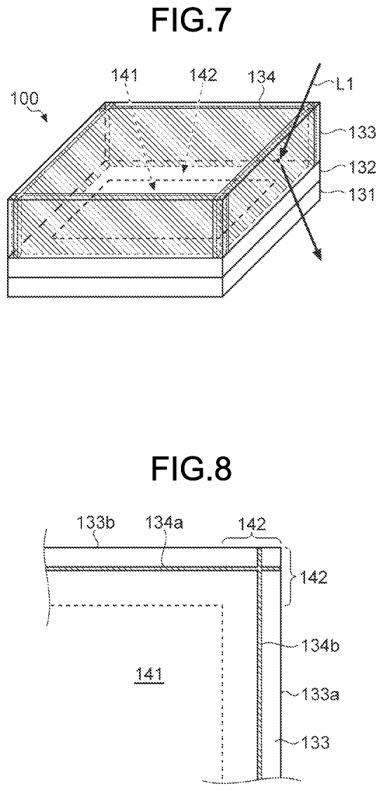

FIG. 6 is a perspective view illustrating glass end surface flare occurring in the image sensor having no light shielding layer according to the first embodiment. FIG. 7 is a perspective view of an image sensor having a light shielding layer according to the first embodiment.

As illustrated in FIG. 6, in a case where the light shielding layer 134 is not provided in the vicinity of the end surface of the glass substrate 133, the light L1 that has entered the end surface of the glass substrate 133 would be incident on the effective pixel region 141, which might cause an occurrence of glass end surface flare that impairs the sharpness of all or part of the image, leading to image quality degradation.

In view of this, in the present embodiment, as illustrated in FIGS. 5 and 7, the light shielding layer 134 is provided along the end surface of the glass substrate 133 on the peripheral region 142 of the semiconductor substrate 131 and in the vicinity of the end surface of the glass substrate 133. For example, in the example illustrated in FIG. 7, there is provided a light shielding layer 134a along an end surface 133a of the glass substrate 133 extending in the vertical direction in the drawing (corresponding to the column direction of the image sensors 100 arranged in a matrix in a semiconductor wafer 131A to be described below), while there is provided a light shielding layer 134b along an end surface 133b of the glass substrate 133 extending in the lateral direction in the drawing (corresponding to the row direction of the image sensors 100 arranged in a matrix in the semiconductor wafer 131A to be described below).

In this manner, with the light shielding layer 134 provided on the end surface of the glass substrate 133, the light L1 incident on the end surface of the glass substrate 133 is blocked by the light shielding layer 134, and incidence on the effective pixel region 141 is reduced, making it possible to suppress the image quality degradation due to occurrence of glass end surface flare.

1.8 Light Shielding Layer

FIG. 8 is an enlarged view obtained by enlarging one corner portion of the image sensor according to the first embodiment.

As illustrated in FIGS. 5 and 7, for example, the light shielding layer 134 according to the present embodiment may penetrate the glass substrate 133 so as to cover from the upper surface to the back surface of the glass substrate 133.

Furthermore, as illustrated in FIG. 8, an end of the light shielding layer 134 in a direction parallel to the back surface of the semiconductor substrate 131 may reach an end surface of the glass substrate 133. For example, the end of the light shielding layer 134a may reach the end surface 133a. Similarly, the end of the light shielding layer 134b may reach the end surface 133b.

Such a light shielding layer 134 can be formed by using, for example, a technique of forming a filament in the glass substrate 133 by irradiating the glass substrate 133 with laser light.

The region irradiated with laser light L2 in the glass substrate 133 is a region in which physical properties related to light transmission such as transmittance (or transparency), reflectance, and refractive index with respect to visible light have been changed from the physical properties of the bare glass. Therefore, by using such a region having changed physical properties as the light shielding layer 134, it is possible to effectively suppress occurrence of glass end surface flare without enlarging the image sensor 100.

However, the present invention is not limited to such a method, and various methods can be adopted as long as the physical properties for visible light can be changed from the physical properties in the region of the bare glass in the glass substrate 133.

Incidentally, the light shielding layer 134 is not necessarily provided on all end surfaces of the glass substrate 133, and may be provided on at least one end surface.

1.9 Manufacturing Method

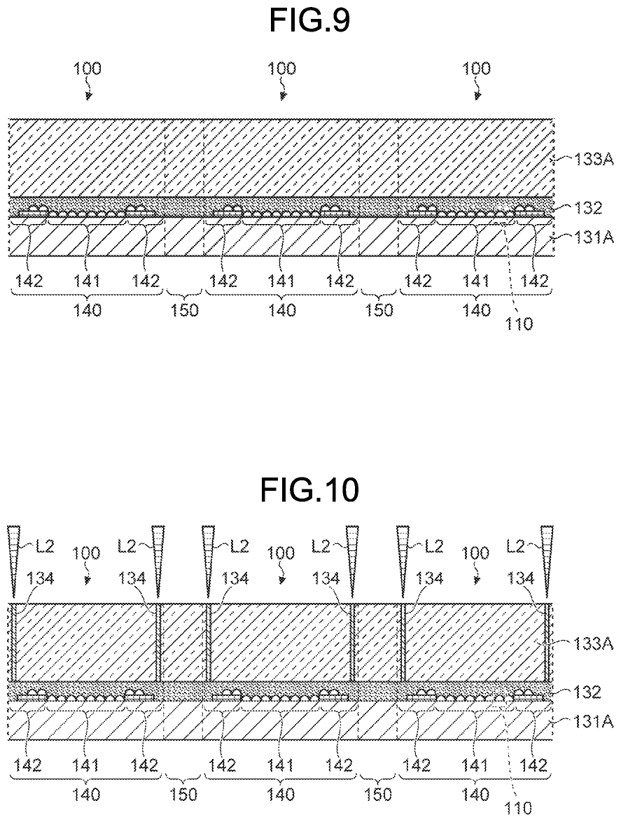

FIGS. 9 to 12 are process cross-sectional views illustrating an example of a method of manufacturing the image sensor according to the first embodiment. In FIGS. 9 to 12, the image sensor 100 is illustrated at a scale different from that in FIG. 5 and the like for clarity of description.

In the present manufacturing method, first, for example, using a wafer level chip size package (WCSP) technology, a plurality of image sensors 100 is fabricated in a semiconductor substrate (hereinafter, referred to as a semiconductor wafer) 131A being in a wafer state before singulation. Subsequently, the glass substrate 133A before singulation is bonded to the back surface (upper surface in the drawings) of the semiconductor wafer 131A using the resin layer 132. With this process, as illustrated in FIG. 9, a bonded substrate including the semiconductor wafer 131A, the resin layer 132, and the glass substrate 133A is prepared.

Note that the image sensor 100 is formed in each of a plurality of chip areas 140 arranged in a matrix on an element formation surface of the semiconductor wafer 131A, for example. Between the adjacent chip areas 140, there is provided a scribe region 150 to be cut at the time of singulation of the image sensor 100. The scribe region 150 has, for example, a grid-like planar shape when the semiconductor wafer 131A is viewed from above the element formation surface.

In FIG. 9, the electrode pad 136, the ball bump 137, and the passivation film 138 on the front surface side (lower surface side in the drawing) of the semiconductor substrate 131 are omitted for simplification of description. However, these may also be fabricated in the semiconductor wafer 131A before singulation.

Next, as illustrated in FIG. 10, a region of the glass substrate 133 located on the peripheral region 142 of the semiconductor substrate 131A is irradiated with the laser light L2 along the scribe region 150, thereby forming the light shielding layer 134 in a part of the glass substrate 133.

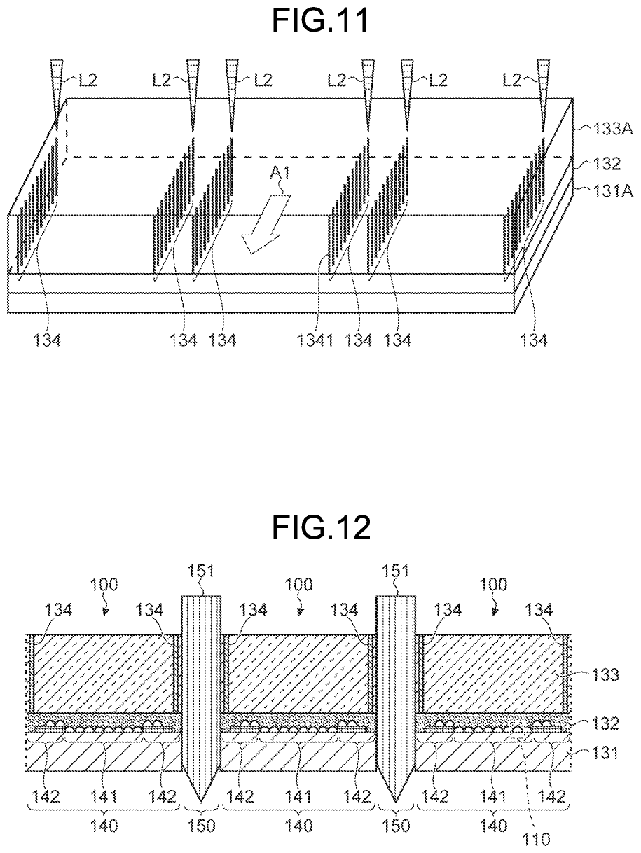

It is possible to use, as the laser light L2, pulse laser light having a pulse width of about 300 femtosecond (fs), for example. The output cycle of the laser light L2 may be about 1 megahertz (MHz), for example. As illustrated in FIG. 11, by outputting the laser light L2 while sliding the stage on which the semiconductor wafer 131A is placed in an extending direction A1 of the scribe region 150, the light shielding layer 134 including a plurality of filaments 1341 arranged along the scribe region 150 is formed on the glass substrate 133 on the peripheral region 142.

The diameter of each of the filaments 1341, in other words, a spot diameter of the laser light L2 may be about 1.5 micrometers (μm), for example. The pitch of the filaments 1341 arranged in the extending direction A1 may be about 3 to 4 μm, for example. These values are not limited to these numerical values, and may be changed to various values.

Furthermore, the pulse intensity of each beam of laser light L2 may be adjusted, for example, to such an extent that the filament 1341 reaches the lower surface of the glass substrate 133A (surface facing the semiconductor wafer 131A). Furthermore, the wavelength of the laser light L2 may be appropriately set in accordance with the material, properties, and the like of the glass substrate 133A.

Next, as illustrated in FIG. 12, the bonded substrate on which the light shielding layer 134 is formed is cut along the scribe region 150 using, for example, a dicing blade 151 such as diamond abrasive grains, thereby achieving singulation into individual image sensors 100. In this case, the end surface of the glass substrate 133 and the end surface of the semiconductor substrate 131 are included in an identical plane. The dicing method is not limited to blade dicing of cutting the wafer with the dicing blade 151 or the like, and various dicing methods such as laser full cut dicing of cutting the wafer with laser light can be used. Alternatively, the glass cut width and the semiconductor wafer cut width may be changed to perform two-stage cutting (stepped cutting).

Execution of the above steps can fabricate the image sensor 100 including the light shielding layer 134 formed along the end surface of the glass substrate 133 as illustrated in FIGS. 5 and 7.

1.10 Action/effects

As described above, according to the present embodiment, the light shielding layer 134 is provided along the end surface of the glass substrate 133 on the peripheral region 142 of the semiconductor substrate 131 and in the vicinity of the end surface of the glass substrate 133. With this configuration, the light L1 incident on the end surface of the glass substrate 133 is blocked by the light shielding layer 134, and incidence on the effective pixel region 141 is reduced, making it possible to suppress the image quality degradation due to occurrence of glass end surface flare.

Furthermore, according to the present embodiment, there is no need to cover the end surface of the glass substrate 133 with a light shielding layer or the like, making it possible to suppress image quality degradation due to occurrence of glass end surface flare while suppressing an enlargement of the image sensor 100.

Furthermore, the present embodiment enables collective formation of the light shielding layer 134 of each image sensor 100 at a wafer fabrication process, making it possible to suppress image quality degradation due to occurrence of glass end surface flare while suppressing deterioration in production efficiency of the image sensor 100.

### 2. Second Embodiment

Next, a solid-state imaging device and an electronic device according to a second embodiment will be described in detail with reference to the drawings. In the following description, the configuration and operation similar to those of the first embodiment will be cited, thereby omitting redundant description.

The electronic device and the solid-state imaging device according to the present embodiment may be similar to the electronic device 1000 and the image sensor 100 described in the first embodiment. However, in the present embodiment, the light shielding layer 134 formed on the glass substrate 133 is replaced with a light shielding layer to be described below.

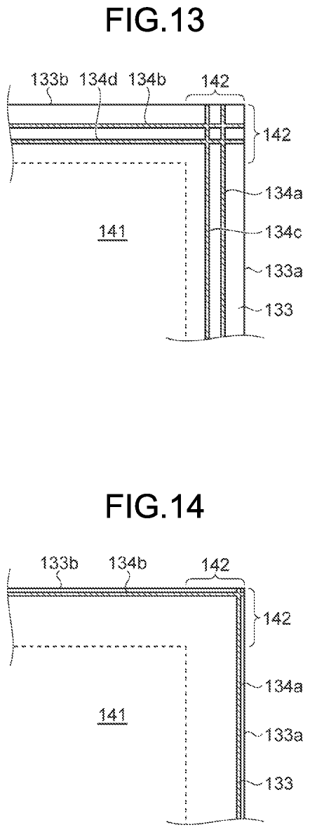

FIG. 13 is an enlarged view obtained by enlarging one corner portion of the image sensor according to a second embodiment.

Although the first embodiment described above is a case where one light shielding layer 134 is provided for each end surface of the glass substrate 133, the light shielding layer 134 provided for each end surface is not limited to one layer, and it is allowable to provide a plurality of layers arranged hierarchically with respect to each end surface.

For example, as illustrated in FIG. 13, in addition to the light shielding layer 134a illustrate in the first embodiment, it is allowable to provide a light shielding layer 134c disposed inside the light shielding layer 134a (closer to the center of the glass substrate 133) on one end surface 133a of the glass substrate 133. Similarly, in addition to the light shielding layer 134b exemplified in the first embodiment, it is allowable to provide a light shielding layer 134d disposed inside the light shielding layer 134b (closer to the center of the glass substrate 133) on the other end surface 133b of the glass substrate 133.

Similarly to the light shielding layers 134a and 134b, which are located in the first layer, the light shielding layers 134c and 134d, which are located in the second layer, may be provided along the end surface of the glass substrate 133 on the peripheral region 142 of the semiconductor substrate 131 and in the vicinity of the end surface of the glass substrate 133.

Furthermore, the ends of the light shielding layers 134c and 134d may reach the end surface 133b or 133a of the glass substrate 133, and may further penetrate from the upper surface to reach the back surface of the glass substrate 133.

In this manner, by doubling the light shielding layer 134 provided on the end surface of the glass substrate 133, it is possible to further reduce the light L1 incident on the effective pixel region 141 via the end surface of the glass substrate 133, leading to further suppression of image quality degradation due to occurrence of glass end surface flare.

Since other configurations, operations, and effects may be similar to those in the above-described embodiment, detailed description thereof will be omitted here.

### 3. Third Embodiment

Next, a solid-state imaging device and an electronic device according to a third embodiment will be described in detail with reference to the drawings. In the following description, the configuration and operation similar to those of the above-described embodiments will be cited, thereby omitting redundant description.

The electronic device and the solid-state imaging device according to the present embodiment may be similar to the electronic device 1000 and the image sensor 100 described in the first embodiment. However, in the present embodiment, the light shielding layer 134 formed on the glass substrate 133 is replaced with a light shielding layer to be described below.

FIG. 14 is an enlarged view obtained by enlarging one corner portion of the image sensor according to a third embodiment.

Although the first embodiment described above is a case where the light shielding layer 134 is provided inside the end surface of the glass substrate 133, the position of the light shielding layer 134 may be still closer to the end surface of the glass substrate 133 as illustrated in FIG. 14. For example, the distance from the end surface 133a of the glass substrate 133 to the light shielding layer 134a and/or the distance from the end surface 133b to the light shielding layer 134b may be 0.2 millimeters (mm) or less.

At that time, all or part of the light shielding layer 134 may form the end surface of the glass substrate 133. For example, a part of the end surface 133a may be formed with the light shielding layer 134a. Similarly, a part of the end surface 133b may be formed with the light shielding layer 134b.

As described above, by bringing the light shielding layer 134 closer to the end surface of the glass substrate 133, it is possible to suppress image quality degradation due to occurrence of glass end surface flare while further suppressing enlargement of the image sensor 100.

Since other configurations, operations, and effects may be similar to those in the above-described embodiment, detailed description thereof will be omitted here.

### 4. Fourth Embodiment

Next, a solid-state imaging device and an electronic device according to a fourth embodiment will be described in detail with reference to the drawings. In the following description, the configuration and operation similar to those of the above-described embodiments will be cited, thereby omitting redundant description.

The electronic device and the solid-state imaging device according to the present embodiment may be similar to the electronic device 1000 and the image sensor 100 described in the first embodiment. However, in the present embodiment, the light shielding layer 134 formed on the glass substrate 133 is replaced with a light shielding layer to be described below.

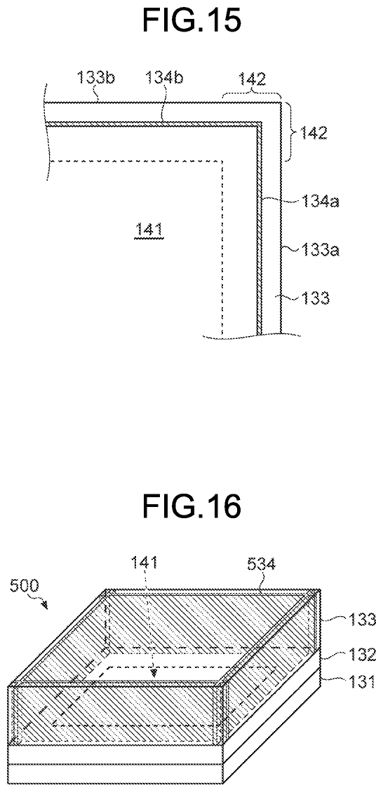

FIG. 15 is an enlarged view obtained by enlarging one corner portion of the image sensor according to a fourth embodiment.

Although the first embodiment described above is a case where the end of the light shielding layer 134 in the direction parallel to the back surface of the semiconductor substrate 131 reaches the end surface of the glass substrate 133, the end of the light shielding layer 134 in the direction parallel to the back surface of the semiconductor substrate 131 does not have to reach the end surface of the glass substrate 133 as illustrated in FIG. 15.

FIG. 15 illustrates a case where the end of the light shielding layer 134a and the end of the light shielding layer 134b coincide with each other. However, the end of the light shielding layer 134a and the end of the light shielding layer 134b do not necessarily coincide with each other, and the light shielding layer 134a and the light shielding layer 134b may intersect with each other.

In this manner, by adopting a structure in which the end of the light shielding layer 134 does not reach the end surface of the glass substrate 133, it is possible to reduce a deterioration in the strength of the corner portion of the glass substrate 133. This makes it possible to suppress occurrence of a defect such as chipping of a corner portion of the glass substrate 133.

Since other configurations, operations, and effects may be similar to those in the above-described embodiment, detailed description thereof will be omitted here.

### 5. Fifth Embodiment

Next, a solid-state imaging device and an electronic device according to a fifth embodiment will be described in detail with reference to the drawings. In the following description, the configuration and operation similar to those of the above-described embodiments will be cited, thereby omitting redundant description.

The electronic device and the solid-state imaging device according to the present embodiment may be similar to the electronic device 1000 and the image sensor 100 described in the first embodiment. However, in the present embodiment, the light shielding layer 134 formed on the glass substrate 133 is replaced with a light shielding layer 534 illustrated in FIG. 16. Note that FIG. 16 is a perspective view of an image sensor including a light shielding layer according to a fifth embodiment.

Although the first embodiment described above is a case where the filament 1341 formed by irradiating the glass substrate 133 with the laser light L2 is used as the light shielding layer 134, the light shielding layer 134 is not limited to the filament 1341 formed by laser processing as described above.

For example, as in an image sensor 500 illustrated in FIG. 16, the light shielding layer 534 in the glass substrate 133 may be an ion implantation region formed by ion implantation of a predetermined dopant into a region (which may be similar to the light shielding layer 134) where the light shielding layer is provided. Even with a method of implanting a predetermined dopant into the glass substrate 133, it is also possible to change the physical properties of the light shielding layer 534 to be different from the physical properties of the bare glass region in the glass substrate 133.

At this time, for example, when the transmittance of the light shielding layer 534 with respect to visible light is 70% (percent) or less, more preferably 50% or less of the transmittance of the bare glass, it is possible to sufficiently reduce the light L1 incident from the end surface of the glass substrate 133, leading to sufficient suppression of image quality degradation due to occurrence of glass end surface flare.

Alternatively, by setting the refractive index of the light shielding layer 534 to be lower than the refractive index of the bare glass, it is possible to increase the reflectance of the light L1 incident at an incident angle of a predetermined angle or more, making it possible to further suppress image quality degradation due to occurrence of glass end surface flare.

Since other configurations, operations, and effects may be similar to those in the above-described embodiment, detailed description thereof will be omitted here.

### 6. Sixth Embodiment

Next, a solid-state imaging device and an electronic device according to a sixth embodiment will be described in detail with reference to the drawings. In the following description, the configuration and operation similar to those of the above-described embodiments will be cited, thereby omitting redundant description.

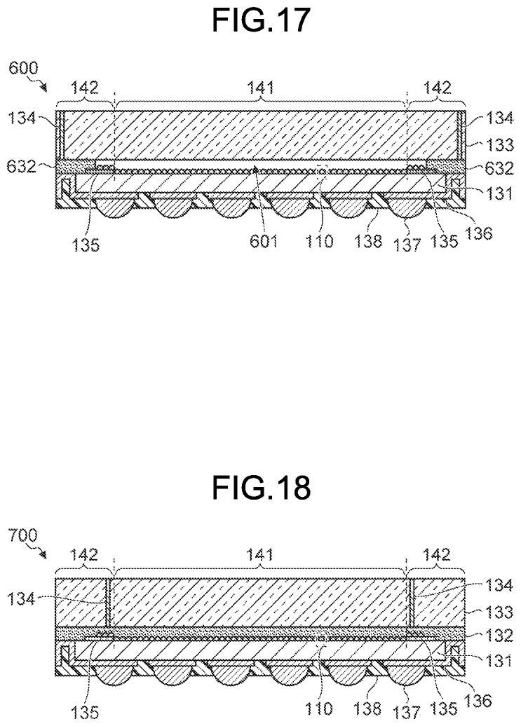

The electronic device according to the present embodiment may be similar to the electronic device 1000 described in the first embodiment. However, in the present embodiment, the image sensor 100 is replaced with an image sensor 600 illustrated in FIG. 17. Note that FIG. 17 is a cross-sectional view illustrating a cross-sectional structure example of an image sensor according to a sixth embodiment.

As illustrated in FIG. 17, the image sensor 600 has a cross-sectional structure similar to that of the image sensor 100 described with reference to FIG. 5 in the first embodiment, for example, in which the resin layer 132 for bonding the semiconductor substrate 131 and the glass substrate 133 to each other is replaced with a resin layer 632 for bonding the semiconductor substrate 131 and the glass substrate 133 in the peripheral region 142 of the semiconductor substrate 131. Due to this configuration, an air gap 601 is formed in the semiconductor substrate 131 between the effective pixel region 141 and the glass substrate 133.

In this manner, even in the structure in which the glass substrate 133 is supported by the resin layer 632 in the peripheral region 142 of the semiconductor substrate 131, in other words, in the structure having the air gap 601 disposed between the effective pixel region 141 and the glass substrate 133 in the semiconductor substrate 131, by providing the light shielding layer 134 on the end surface of the glass substrate 133, it is possible, by the light shielding layer 134, to block the light L1 incident on the end surface of the glass substrate 133 to reduce the incidence on the effective pixel region 141, making it possible to suppress the image quality degradation due to occurrence of the glass end surface flare.

Since other configurations, operations, and effects may be similar to those in the above-described embodiment, detailed description thereof will be omitted here.

### 7. Seventh Embodiment

Next, a solid-state imaging device and an electronic device according to a seventh embodiment will be described in detail with reference to the drawings. In the following description, the configuration and operation similar to those of the above-described embodiments will be cited, thereby omitting redundant description.

The electronic device according to the present embodiment may be similar to the electronic device 1000 described in the first embodiment. However, in the present embodiment, the image sensor 100 is replaced with an image sensor 700 illustrated in FIG. 18. Note that FIG. 18 is a cross-sectional view illustrating a cross-sectional structure example of an image sensor according to the seventh embodiment.

The above-described embodiment is an exemplary case where the light shielding layer 134 is provided in the vicinity (refer to FIG. 8, for example) or in the neighborhood (refer to FIG. 14, for example) of the end surface of the glass substrate 133 on the peripheral region 142 of the semiconductor substrate 131. However, the position of the light shielding layer 134 is not limited to the vicinity or the neighborhood of the end surface of the glass substrate 133.

For example, like the image sensor 700 illustrated in FIG. 18, the light shielding layer 134 may be provided on the OPB film 135 in the peripheral region 142 of the semiconductor substrate 131. In other words, the light shielding layer 134 may be provided at a position close to the effective pixel region 141 on the peripheral region 142 of the semiconductor substrate 131.

In this manner, by bringing the light shielding layer 134 close to the effective pixel region 141, it is possible to suppress incidence, on the effective pixel region 141, of not only the light L1 that has entered from the end surface of the glass substrate 133 but also the light that has obliquely entered from the upper surface in the vicinity of the end surface of the glass substrate 133. This makes it possible to further suppress image quality degradation due to occurrence of a flare phenomenon including the glass end surface flare.

Since other configurations, operations, and effects may be similar to those in the above-described embodiment, detailed description thereof will be omitted here.

### 8. Eighth Embodiment

Next, a solid-state imaging device and an electronic device according to an eighth embodiment will be described in detail with reference to the drawings. In the following description, the configuration and operation similar to those of the above-described embodiments will be cited, thereby omitting redundant description.

The above-described embodiment is an exemplary case where the light shielding layer 134 is formed in parallel with the end surface of the glass substrate 133, in other words, perpendicular to the upper surface and the lower surface of the glass substrate 133. However, the light shielding layer 134 need not be perpendicular to the upper surface or the lower surface of the glass substrate 133.

In the present embodiment, a case where the light shielding layer 134 is inclined with respect to the upper surface and the lower surface of the glass substrate 133 will be described with some examples. Note that the electronic device according to the present embodiment may be similar to the electronic device 1000 described in the first embodiment.

8.1 First Example

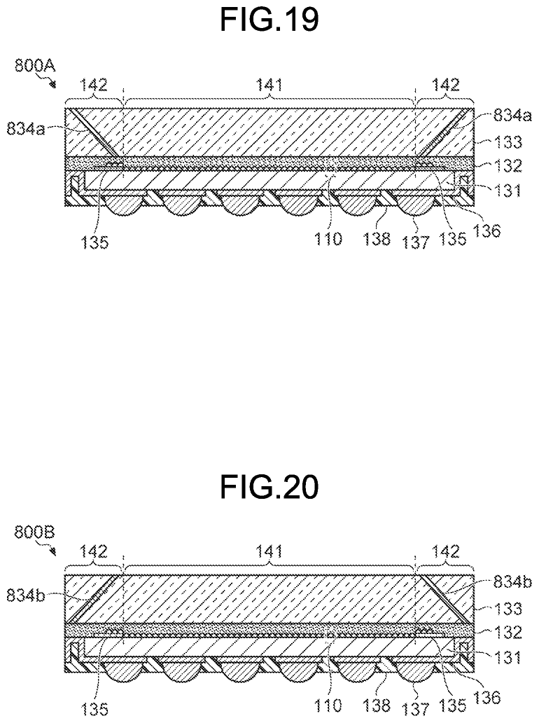

FIG. 19 is a cross-sectional view illustrating a cross-sectional structure example of the image sensor according to a first example. As illustrated in FIG. 19, an image sensor 800A according to the first example has a cross-sectional structure similar to that of the image sensor 100 described with reference to FIG. 5 and the like in the first embodiment in which the light shielding layer 134 is replaced with a light shielding layer 834a inclined with respect to the upper surface and the lower surface of the glass substrate 133.

More specifically, the light shielding layer 834a according to the present embodiment is inclined such that an end on the upper surface side of the glass substrate 133 (hereinafter, referred to as an upper end) is close to the end surface of the glass substrate 133 while an end on the lower surface side of the glass substrate 133 (hereinafter, referred to as a lower end) is close to the effective pixel region 141 of the semiconductor substrate 131. At that time, the lower end of the light shielding layer 834a may be positioned on the OPB film 135 in the peripheral region 142.

8.2 Second Example

FIG. 20 is a cross-sectional view illustrating a cross-sectional structure example of the image sensor according to a second example. As illustrated in FIG. 20, an image sensor 800B according to the second example has a cross-sectional structure similar to that of the image sensor 100 described with reference to FIG. 5 and the like in the first embodiment, in which the light shielding layer 134 is replaced with a light shielding layer 834b inclined with respect to the upper surface and the lower surface of the glass substrate 133.

More specifically, the light shielding layer 834b according to the present embodiment is inclined such that an upper end thereof is close to the effective pixel region 141 of the semiconductor substrate 131 and a lower end thereof is close to the end surface of the glass substrate 133. At that time, the upper end of the light shielding layer 834a may be positioned on the OPB film 135 in the peripheral region 142.

8.3 Action/Effects

As described above, even in a case where the light shielding layer 834a or 834b is inclined with respect to the upper surface and the lower surface of the glass substrate 133, it is also possible to suppress the incidence of the light L1 that has entered from the end surface of the glass substrate 133 on the effective pixel region 141, leading to suppression of image quality degradation due to occurrence of glass end surface flare.

Incidentally, the light shielding layers 834a and 834b inclined with respect to the upper surface and the lower surface of the glass substrate 133 can be formed, for example, by inclining a stage on which the bonded substrate is placed with respect to the optical axis of the laser light L2 or by inclining the optical axis of the laser light L2 with respect to the stage when forming the light shielding layer 834a or 834b.

Since other configurations, operations, and effects may be similar to those in the above-described embodiment, detailed description thereof will be omitted here.

### 9. Ninth Embodiment

Next, a solid-state imaging device and an electronic device according to a ninth embodiment will be described in detail with reference to the drawings. In the following description, the configuration and operation similar to those of the above-described embodiments will be cited, thereby omitting redundant description.

The above-described embodiment is an exemplary case where the light shielding layer 134 is formed so as to pass through the glass substrate 133 from the upper surface to the lower end, in other words, penetrate the glass substrate 133. The formation region of the light shielding layer 134, however, is not limited to the range from the upper surface to the lower end.

In the present embodiment, the formation region of the light shielding layer 134 will be described with some examples. Note that the electronic device according to the present embodiment may be similar to the electronic device 1000 described in the first embodiment.

9.1 First Example

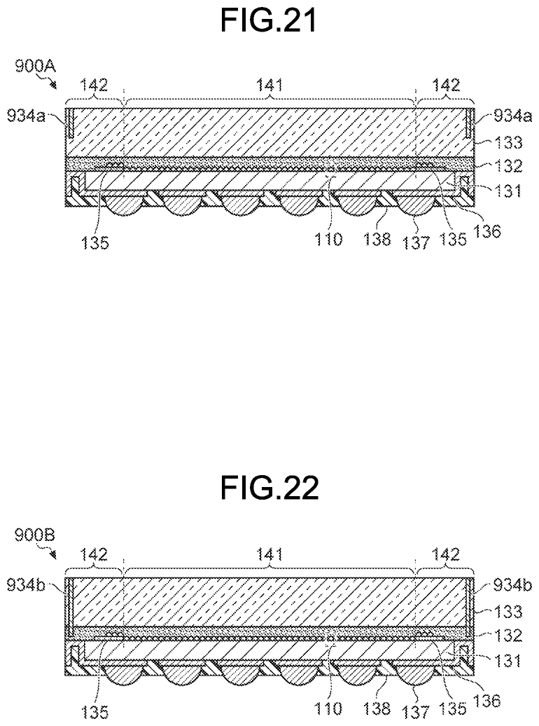

FIG. 21 is a cross-sectional view illustrating a cross-sectional structure example of the image sensor according to a first example. As illustrated in FIG. 21, an image sensor 900A according to the first example has a cross-sectional structure similar to that of the image sensor 100 described with reference to FIG. 5 and the like in the first embodiment in which the light shielding layer 134 is replaced with a light shielding layer 934a provided from the upper surface of the glass substrate 133 to the middle of the glass substrate 133. That is, in the first example, the end of the light shielding layer 934a in a direction perpendicular to the back surface of the semiconductor substrate 131, which is an end on the semiconductor substrate 131 side, may be separated from the lower surface of the glass substrate 133.

9.2 Second Example

FIG. 22 is a cross-sectional view illustrating a cross-sectional structure example of the image sensor according to the second example. As illustrated in FIG. 22, an image sensor 900B according to the second example has a cross-sectional structure similar to that of the image sensor 100 described with reference to FIG. 5 and the like in the first embodiment, in which the light shielding layer 134 is replaced with a light shielding layer 934b that penetrates the glass substrate 133 and reaches the resin layer 132. That is, in the second example, the end of the light shielding layer 934b in the direction perpendicular to the back surface of the semiconductor substrate 131, which is an end on the semiconductor substrate 131 side, reaches the resin layer 132.

9.3 Action/Effects

As described above, even in a case of using the light shielding layer 934a passing from the upper surface to the middle of the glass substrate 133 or the light shielding layer 934b penetrating the glass substrate 133 to reach the resin layer 132, it is possible to suppress the incidence of the light L1 that has entered from the end surface of the glass substrate 133 on the effective pixel region 141, leading to suppression of image quality degradation due to occurrence of glass end surface flare.

Incidentally, the light shielding layer 934a passing from the upper surface to the middle of the glass substrate 133 and the light shielding layer 934b that penetrates the glass substrate 133 and reaches the resin layer 132 can be formed, for example, by adjusting the intensity or pulse width of the laser light L2 when the light shielding layer 934a or 934b is formed.

Since other configurations, operations, and effects may be similar to those in the above-described embodiment, detailed description thereof will be omitted here.

### 10. Tenth Embodiment

When forming the light shielding layer 134, 134a, 134b, 134c, 134d, 534, 834a, 834b, 934a, or 934b according to the above-described embodiments by laser irradiation, ion implantation, or the like, there is a case where laser light, ions, or the like at the time of formation unintentionally reach the resin layer 132, resulting in degeneration or deterioration of a region (hereinafter, referred to as a degenerated/deteriorated region) subjected to the laser irradiation, ion implantation, or the like in the resin layer 132. The degenerated/deteriorated region might cause reliability impairing defects, such as peeling and moisture ingress.

In view of this, the present embodiment uses a configuration in which the degenerated/deteriorated region, which is formed in the resin layer 132 at formation of the light shielding layer, does not exist in the image sensor after singulation. This makes it possible to reduce the occurrence of reliability impairing defects such as peeling and moisture ingress caused by the degenerated/deteriorated region.

For example, as in the image sensor 800B (refer to FIG. 20) according to the second example of the eighth embodiment described above, in a case where the inclined light shielding layer 834b is provided such that the upper end thereof is close to the effective pixel region 141 of the semiconductor substrate 131 and the lower end thereof is close to the end surface of the glass substrate 133, by controlling the distance from the glass substrate 133 on the upper end side of the light shielding layer 834b and the inclination angle of the light shielding layer 834b with respect to the end surface of the glass substrate 133, it is possible to adjust the position of the region (corresponding to the degenerated/deteriorated region) of the resin layer 132 existing on an extension line of the irradiation axis of the laser light L2 or the ion implantation axis at the time of formation of the light shielding layer 834b.

Furthermore, the resin layer 132 located in the scribe region 150 is removed at singulation of the image sensor 100 and the like (refer to FIG. 12, for example).

In view of these, for example, the second example of the eighth embodiment, the distance from the glass substrate 133 on the upper end side of the light shielding layer 834b and the inclination angle of the light shielding layer 834b with respect to the end surface of the glass substrate 133 are controlled so that the degenerated/deteriorated region to be formed in the resin layer 132 at the formation of the light shielding layer 834b will be located within the scribe region 150. This makes it possible to have a configuration in which the degenerated/deteriorated region formed in the resin layer 132 at the time of forming the light shielding layer 834b does not exist in the image sensor after singulation.

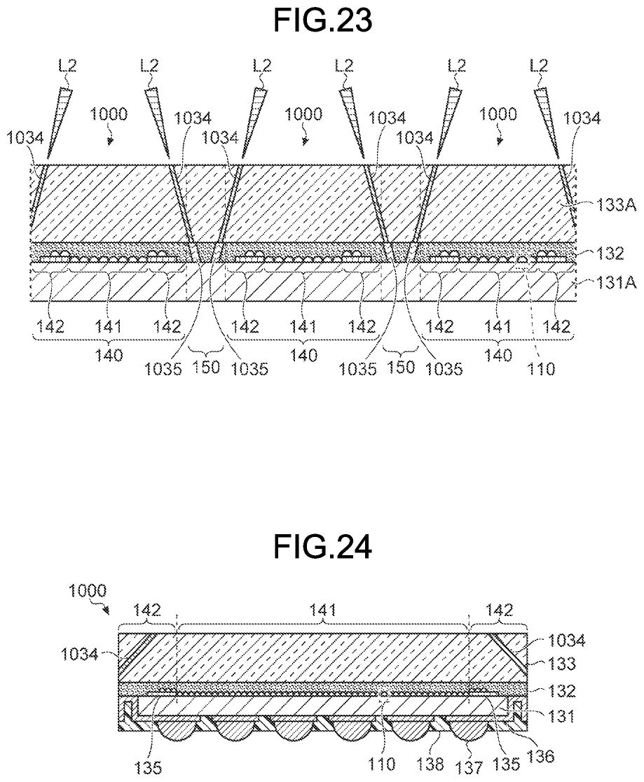

FIG. 23 is a process cross-sectional view illustrating an example of the method of manufacturing the image sensor according to the tenth embodiment, being a diagram illustrating steps corresponding to the steps described with reference to FIG. 10 in the first embodiment. That is, in the present embodiment, the step of forming the light shielding layer 134 described with reference to FIG. 10 in the manufacturing method described with reference to FIGS. 9 to 12 in the first embodiment is replaced with the step illustrated in FIG. 23.

As illustrated in FIG. 23, in the present embodiment, for example, a laser light L2 for forming a light shielding layer 1034 (for example, corresponding to the light shielding layer 834b) is applied at a predetermined inclination angle with respect to a boundary surface (surface perpendicular to the upper surface of the glass substrate 133A) between the chip area 140 and the scribe region 150. At that time, the irradiation position and the inclination of the optical axis (irradiation axis) of the laser light L2 are adjusted such that the region where the traveling direction of the laser light L2 intersects the resin layer 132, that is, a modified/deteriorated region 1035 is located within the scribe region 150.

Thereafter, as described with reference to FIG. 12 in the first embodiment, the image sensor 1000 is singulated into individual chips by cutting the scribe region 150. At this time, since the modified/deteriorated region 1035 in the scribe region 150 is also removed, there will be no modified/deteriorated region 1035 remaining in the chip of the image sensor 1000 after singulation as illustrated in FIG. 24. Note that FIG. 24 is a cross-sectional view illustrating a cross-sectional structure example of an image sensor according to the tenth embodiment.

As illustrated in FIG. 24, the image sensor 1000 after singulation includes the light shielding layer 1034 extending from the upper surface to the end surface of the glass substrate 133. Accordingly, a part of the light shielding layer 1034 is exposed on the end surface of the glass substrate 133 after singulation.

Here, a specific example of the irradiation position and optical axis (irradiation axis) inclination regarding the laser light L2 will be described. Note that the present specific example is an exemplary case where the thickness of the glass substrate 133 (133A) is 130 μm, the thickness of the resin layer 132 is 30 μm, the width of the scribe region 150 is 80 μm, the width of the modified/deteriorated region 1035 formed in the resin layer 132 by laser irradiation is 10 μm, and the irradiation position of the laser light L2 on the upper surface of the glass substrate 133A (the incident position of the optical axis C2 of the laser light L2) is set to a position 30 μm inside a boundary 152 between the scribe region 150 and the chip area 140. Note that the inside the boundary 152 refers to the chip area 140 side.

Furthermore, in the above configuration, in order to avoid preserving the modified/deteriorated region 1035 in the image sensor 1000 after singulation when the scribe region 150 is removed, for example, there is a need to set the position where the optical axis C2 of the laser light L2 is incident on the upper surface of the resin layer 132 to be at least 5 μm outside the boundary 152 between the scribe region 150 and the chip area 140. The outside the boundary 152 refers to the scribe region 150 side.

Therefore, the present specific example causes the optical axis C2 of the laser light L2 to be incident on the upper surface of the resin layer 132 at a position outside the boundary 152 between the scribe region 150 and the chip area 140 by 5 μm or more.

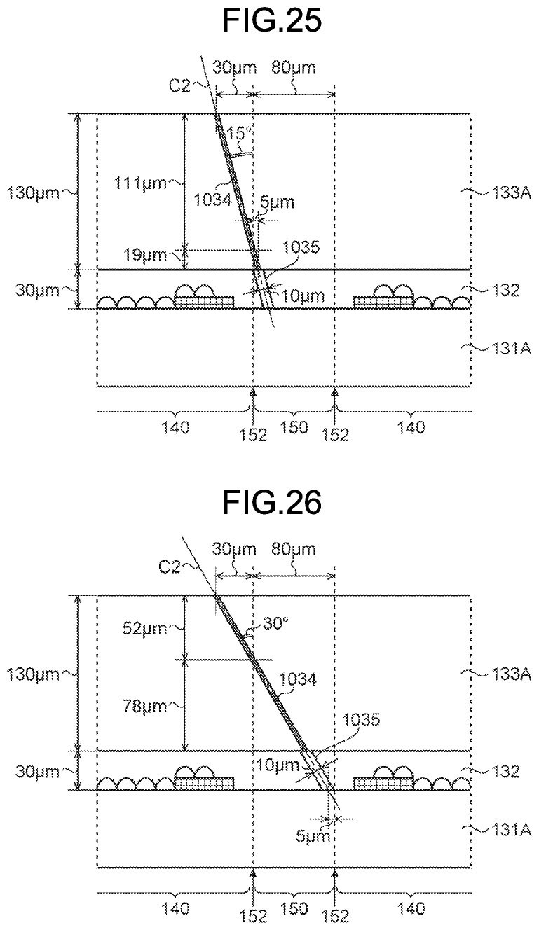

FIG. 25 is a cross-sectional view in a case where the inclination angle of the light shielding layer is minimized in the specific example of the tenth embodiment, and FIG. 26 is a cross-sectional view in a case where the inclination angle of the light shielding layer is maximized in the specific example of the tenth embodiment.

As illustrated in FIGS. 25 and 26, in the present specific example, the inclination angle of the light shielding layer 1034 with respect to the end surface of the glass substrate 133 can be adjusted in the range of 15° or more and 30° or less. That is, by adjusting the inclination angle of the light shielding layer 1034 in the range of 15° or more and 30° or less, it is possible to suppress the occurrence of glass end surface flare while reducing the occurrence of reliability impairing defects such as peeling and moisture ingress.

Note that the numerical values illustrated in FIGS. 25 and 26 are merely specific examples, and by appropriately adjusting the incident position of the laser light L2 on the upper surface of the glass substrate 133, the inclination angle of the optical axis C2, and the like in accordance with the thickness of the glass substrate 133, the thickness of the resin layer 132, the width of the scribe region 150, and the like, it is possible to suppress the occurrence of glass end surface flare while reducing the occurrence of reliability impairing defects such as peeling and moisture ingress.

Furthermore, although the above description is an exemplary case where the modified/deteriorated region 1035 is completely removed from the image sensor 1000 after being formed into a chip, the removing mode is not limited thereto, and a part of the modified/deteriorated region 1035 may remain in the image sensor 1000 after being formed into a chip. Even in this case, it is possible to reduce the occurrence of reliability impairing defects such as peeling and moisture ingress.

Since other configurations, operations, and effects may be similar to those in the above-described embodiment, detailed description thereof will be omitted here.

### 11. Example of Application to Moving Object

The technology according to the present disclosure (the present technology) is applicable to various products. The technology according to the present disclosure may be applied to devices mounted on any of moving objects such as automobiles, electric vehicles, hybrid electric vehicles, motorcycles, bicycles, personal mobility, airplanes, drones, ships, and robots.

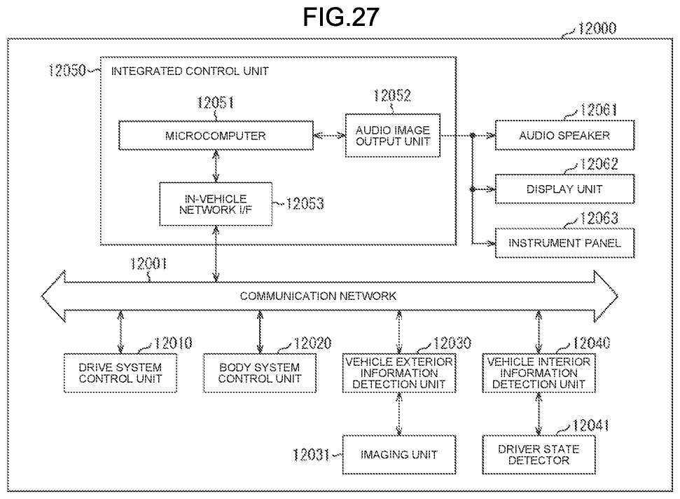

FIG. 27 is a block diagram illustrating a schematic configuration example of a vehicle control system, which is an example of a moving body control system to which the technology according to the present disclosure is applicable.

A vehicle control system 12000 includes a plurality of electronic control units connected via a communication network 12001. In the example illustrated in FIG. 27, the vehicle control system 12000 includes a drive system control unit 12010, a body system control unit 12020, a vehicle exterior information detection unit 12030, a vehicle interior information detection unit 12040, and an integrated control unit 12050. Furthermore, as a functional configuration of the integrated control unit 12050, a microcomputer 12051, an audio image output unit 12052, and an in-vehicle network interface (I/F) 12053 are illustrated.

The drive system control unit 12010 controls the operation of the device related to the drive system of the vehicle in accordance with various programs. For example, the drive system control unit 12010 functions as a control device of a driving force generation device that generates a driving force of a vehicle such as an internal combustion engine or a driving motor, a driving force transmission mechanism that transmits a driving force to the wheels, a steering mechanism that adjusts steering angle of the vehicle, a braking device that generates a braking force of the vehicle, or the like.

The body system control unit 12020 controls the operation of various devices mounted on the vehicle body in accordance with various programs. For example, the body system control unit 12020 functions as a control device for a keyless entry system, a smart key system, a power window device, or various lamps such as a head lamp, a back lamp, a brake lamp, a turn signal lamp, or a fog lamp. In this case, the body system control unit 12020 can receive input of radio waves transmitted from a portable device that substitutes for the key or signals from various switches. The body system control unit 12020 receives the input of these radio waves or signals and controls the door lock device, the power window device, the lamp, or the like, of the vehicle.

The vehicle exterior information detection unit 12030 detects information outside the vehicle equipped with the vehicle control system 12000. For example, an imaging unit 12031 is connected to the vehicle exterior information detection unit 12030. The vehicle exterior information detection unit 12030 causes the imaging unit 12031 to capture an image of the exterior of the vehicle and receives the captured image. The vehicle exterior information detection unit 12030 may perform an object detection process or a distance detection process of people, vehicles, obstacles, signs, or characters on the road surface based on the received image.

The imaging unit 12031 is an optical sensor that receives light and outputs an electric signal corresponding to the amount of received light. The imaging unit 12031 can output the electric signal as an image and also as distance measurement information. Furthermore, the light received by the imaging unit 12031 may be visible light or invisible light such as infrared rays.

The vehicle interior information detection unit 12040 detects vehicle interior information. The vehicle interior information detection unit 12040 is connected to a driver state detector 12041 that detects the state of the driver, for example. The driver state detector 12041 may include a camera that images the driver, for example. The vehicle interior information detection unit 12040 may calculate the degree of fatigue or degree of concentration of the driver or may determine whether the driver is dozing off based on the detection information input from the driver state detector 12041.

The microcomputer 12051 can calculate a control target value of the driving force generation device, the steering mechanism, or the braking device based on vehicle external/internal information obtained by the vehicle exterior information detection unit 12030 or the vehicle interior information detection unit 12040, and can output a control command to the drive system control unit 12010. For example, the microcomputer 12051 can perform cooperative control for the purpose of achieving a function of an advanced driver assistance system (ADAS) including collision avoidance or impact mitigation of vehicles, follow-up running based on an inter-vehicle distance, cruise control, vehicle collision warning, vehicle lane departure warning, or the like.

Furthermore, it is allowable such that the microcomputer 12051 controls the driving force generation device, the steering mechanism, the braking device, or the like, based on the information regarding the surroundings of the vehicle obtained by the vehicle exterior information detection unit 12030 or the vehicle interior information detection unit 12040, thereby performing cooperative control for the purpose of autonomous driving or the like, in which the vehicle performs autonomous traveling without depending on the operation of the driver.

Furthermore, the microcomputer 12051 can output a control command to the body system control unit 12020 based on the vehicle exterior information acquired by the vehicle exterior information detection unit 12030. For example, the microcomputer 12051 can control the head lamp in accordance with the position of the preceding vehicle or the oncoming vehicle sensed by the vehicle exterior information detection unit 12030, and thereby can perform cooperative control aiming at antiglare such as switching the high beam to low beam.

The audio image output unit 12052 transmits an output signal in the form of at least one of audio or image to an output device capable of visually or audibly notifying the occupant of the vehicle or the outside of the vehicle of information. In the example of FIG. 27, an audio speaker 12061, a display unit 12062, and an instrument panel 12063 are illustrated as exemplary output devices. The display unit 12062 may include, for example, at least one of an onboard display and a head-up display.

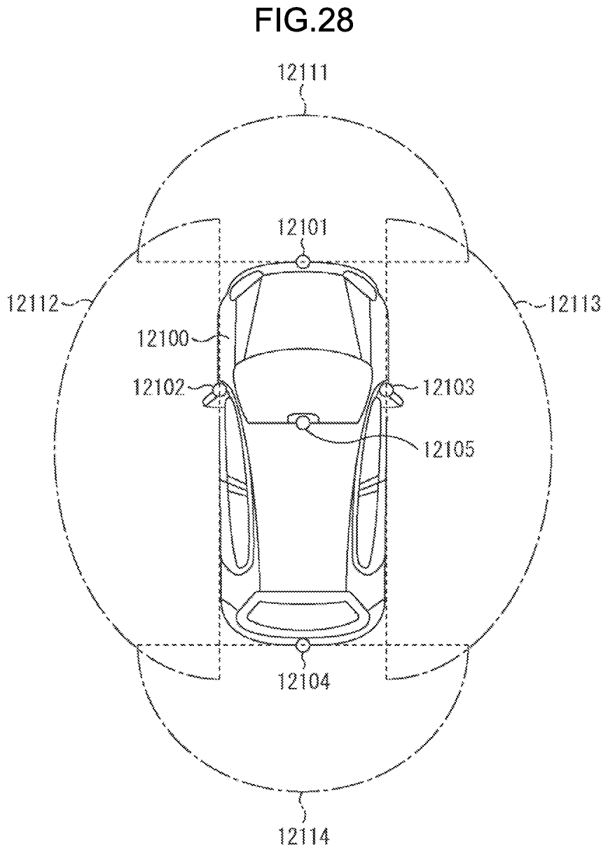

FIG. 28 is a diagram illustrating an example of an installation position of the imaging unit 12031.

In FIG. 28, the imaging unit 12031 includes imaging units 12101, 12102, 12103, 12104, and 12105.

For example, the imaging units 12101, 12102, 12103, 12104, and 12105 are installed at positions on a vehicle 12100, including a front nose, a side mirror, a rear bumper, a back door, an upper portion of the windshield in a vehicle interior, or the like. The imaging unit 12101 provided on the front nose and the imaging unit 12105 provided on the upper portion of the windshield in the vehicle interior mainly acquire an image in front of the vehicle 12100. The imaging units 12102 and 12103 provided in the side mirrors mainly acquire images of the side of the vehicle 12100. The imaging unit 12104 provided on the rear bumper or the back door mainly acquires an image behind the vehicle 12100. The imaging unit 12105 provided at an upper portion of the windshield in the vehicle interior is mainly used for detecting a preceding vehicle or a pedestrian, an obstacle, a traffic light, a traffic sign, a lane, or the like.

Note that FIG. 28 illustrates an example of the imaging range of the imaging units 12101 to 12104. An imaging range 12111 indicates an imaging range of the imaging unit 12101 provided on the front nose, imaging ranges 12112 and 12113 indicate imaging ranges of the imaging units 12102 and 12103 provided on the side mirrors, respectively, and an imaging range 12114 indicates an imaging range of the imaging unit 12104 provided on the rear bumper or the back door. For example, by superimposing pieces of image data captured by the imaging units 12101 to 12104, it is possible to obtain a bird's-eye view image of the vehicle 12100 as viewed from above.

At least one of the imaging units 12101 to 12104 may have a function of acquiring distance information. For example, at least one of the imaging units 12101 to 12104 may be a stereo camera including a plurality of imaging elements, or an imaging element having pixels for phase difference detection.

For example, the microcomputer 12051 can calculate a distance to each of three-dimensional objects in the imaging ranges 12111 to 12114 and a temporal change (relative speed with respect to the vehicle 12100) of the distance based on the distance information obtained from the imaging units 12101 to 12104, and thereby can extract a three-dimensional object traveling at a predetermined speed (for example, 0 km/h or more) in substantially the same direction as the vehicle 12100 being the closest three-dimensional object on the traveling path of the vehicle 12100, as a preceding vehicle. Furthermore, the microcomputer 12051 can set an inter-vehicle distance to be ensured in front of the preceding vehicle in advance, and can perform automatic brake control (including follow-up stop control), automatic acceleration control (including follow-up start control), or the like. In this manner, it is possible to perform cooperative control for the purpose of autonomous driving or the like, in which the vehicle autonomously travels without depending on the operation of the driver.

For example, based on the distance information obtained from the imaging units 12101 to 12104, the microcomputer 12051 can extract three-dimensional object data regarding the three-dimensional object with classification into three-dimensional objects, such as a two-wheeled vehicle, a regular vehicle, a large vehicle, a pedestrian, and other three-dimensional objects such as a utility pole, and can use the data for automatic avoidance of obstacles. For example, the microcomputer 12051 distinguishes obstacles around the vehicle 12100 into obstacles having high visibility to the driver of the vehicle 12100 and obstacles having low visibility to the driver. Subsequently, the microcomputer 12051 determines a collision risk indicating the risk of collision with each of obstacles. When the collision risk is a set value or more and there is a possibility of collision, the microcomputer 12051 can output an alarm to the driver via the audio speaker 12061 and the display unit 12062, and can perform forced deceleration and avoidance steering via the drive system control unit 12010, thereby achieving driving assistance for collision avoidance.

At least one of the imaging units 12101 to 12104 may be an infrared camera that detects infrared rays. For example, the microcomputer 12051 can recognize a pedestrian by determining whether or not a pedestrian is present in the captured images of the imaging units 12101 to 12104. Such pedestrian recognition is performed, for example, by a procedure of extracting feature points in a captured image of the imaging units 12101 to 12104 as an infrared camera, and by a procedure of performing pattern matching processing on a series of feature points indicating the contour of the object to discriminate whether or not it is a pedestrian. When the microcomputer 12051 determines that a pedestrian is present in the captured images of the imaging units 12101 to 12104 and recognizes a pedestrian, the audio image output unit 12052 causes the display unit 12062 to perform superimposing display of a rectangular contour line for emphasis to the recognized pedestrian. Furthermore, the audio image output unit 12052 may cause the display unit 12062 to display an icon indicating a pedestrian or the like at a desired position.

The embodiments of the present disclosure have been described above. However, the technical scope of the present disclosure is not limited to the above-described embodiments, and various modifications can be made without departing from the scope of the present disclosure. Moreover, it is allowable to combine the components across different embodiments and a modification as appropriate.

The effects described in individual embodiments of the present specification are merely examples, and thus, there may be other effects, not limited to the exemplified effects.

Note that the present technology can also have the following configurations.

(1)

A solid-state imaging device comprising:

a semiconductor substrate including a light receiving element in a first region on a first surface;

a glass substrate facing the first surface of the semiconductor substrate;

a resin layer that supports the glass substrate against the first surface; and

a layer provided in the glass substrate, the layer being provided in a third region corresponding to a second region surrounding the first region of the semiconductor substrate in a substrate thickness direction of the semiconductor substrate, the layer having a physical property with respect to visible light different from a physical property of the glass substrate.

(2)

The solid-state imaging device according to (1), wherein at least one of transmittance, reflectance, or refractive index of the layer with respect to visible light is different from transmittance, reflectance, or refractive index of the glass substrate with respect to visible light.

(3)

The solid-state imaging device according to (1) or (2), wherein the layer is provided in the third region including a region sandwiched between at least one end surface of the end surfaces of the glass substrate, and the first region.

(4)

The solid-state imaging device according to any one of (1) to (3),

wherein the layer is closer to an end surface of the glass substrate than to the first region.

(5)

The solid-state imaging device according to (4), wherein the layer forms a part of the end surface of the glass substrate.

(6)

The solid-state imaging device according to any one of (1) to (3),

wherein the semiconductor substrate further includes a light shielding film provided on the second region on the first surface so as to surround the first region, and

the layer is provided at a position corresponding to the light shielding film in the substrate thickness direction.

(7)

The solid-state imaging device according to any one of (1) to (6),

wherein the layer includes a plurality of layers arranged hierarchically with respect to an end surface of the glass substrate.

(8)

The solid-state imaging device according to any one of (1) to (3),

wherein the layer is inclined with respect to a surface of the glass substrate facing the semiconductor substrate.

(9)

The solid-state imaging device according to (8), in which the layer extends from a surface of the glass substrate opposite to the surface facing the semiconductor substrate to an end surface of the glass substrate.

(10)

The solid-state imaging device according to (8) or (9),

wherein the semiconductor substrate further includes a light shielding film provided on the second region on the first surface so as to surround the first region, and

one of ends of the layer in a direction perpendicular to the first surface is disposed at a position corresponding to the light shielding film in the substrate thickness direction.

(11)

The solid-state imaging device according to any one of (1) to (10),

wherein an end of the layer in a direction parallel to the first surface reaches an end surface of the glass substrate.

(12)

The solid-state imaging device according to any one of (1) to (10),

wherein an end of the layer in a direction parallel to the first surface is separated from an end surface of the glass substrate.

(13)

The solid-state imaging device according to any one of (1) to (12),

wherein the layer reaches a second surface of the glass substrate facing the semiconductor substrate from a third surface opposite to the second surface of the glass substrate.

(14)

The solid-state imaging device according to any one of (1) to (12),

wherein an end of the layer in a direction perpendicular to the first surface, the end being an end on the semiconductor substrate side, is separated from a second surface of the glass substrate facing the semiconductor substrate.

(15)

The solid-state imaging device according to any one of (1) to (12),

wherein an end of the layer in a direction perpendicular to the first surface, the end being an end on the semiconductor substrate side, reaches the resin layer.

(16)

The solid-state imaging device according to any one of (1) to (15),

wherein the layer is a filament formed by modifying a part of the glass substrate.

(17)

The solid-state imaging device according to any one of (1) to (15),

wherein the layer is an ion implantation region formed by implanting a dopant into a part of the glass substrate.

(18)

The solid-state imaging device according to any one of (1) to (17),

wherein the resin layer covers the first region in the semiconductor substrate.

(19)

The solid-state imaging device according to any one of (1) to (17),

wherein an air gap is provided between the first region in the semiconductor substrate and the glass substrate.

(20)

The solid-state imaging device according to any one of (1) to (19),

wherein an end surface of the semiconductor substrate and an end surface of the glass substrate are included in an identical plane.

(21)

An electronic device comprising:

a solid-state imaging device;

an optical system that forms an image based on incident light onto a light receiving surface of the solid-state imaging device; and

a processor that controls the solid-state imaging device,

wherein the solid-state imaging device includes:

a semiconductor substrate including a light receiving element in a first region on a first surface;

a glass substrate facing the first surface of the semiconductor substrate;

a resin layer that supports the glass substrate against the first surface; and

a layer provided in the glass substrate, the layer being provided in a third region corresponding to a second region surrounding the first region of the semiconductor substrate in a substrate thickness direction of the semiconductor substrate, the layer having a physical property with respect to visible light different from a physical property of the glass substrate.

### REFERENCE SIGNS LIST

100, 500, 600, 700, 800A, 800B, 900A, 900B, 1000 IMAGE SENSOR (SOLID-STATE IMAGING DEVICE)
101 PIXEL ARRAY UNIT
102 VERTICAL DRIVE CIRCUIT
103 COLUMN PROCESSING CIRCUIT
104 HORIZONTAL DRIVE CIRCUIT
105 SYSTEM CONTROL UNIT
108 SIGNAL PROCESSING UNIT
109 DATA STORAGE UNIT
110 UNIT PIXEL
111 TRANSFER TRANSISTOR
112 RESET TRANSISTOR
113 AMPLIFICATION TRANSISTOR
114 SELECTION TRANSISTOR
121 LIGHT RECEIVING CHIP
122 CIRCUIT CHIP
131 SEMICONDUCTOR SUBSTRATE
131A SEMICONDUCTOR WAFER
132, 632 RESIN LAYER
133, 133A GLASS SUBSTRATE
133a, 133b END SURFACE
134, 134a, 134b, 134c, 134d, 534, 834a, 834b, 934a, 934b, 1034 LIGHT SHIELDING LAYER
135 OPB FILM
136 ELECTRODE PAD
137 BALL BUMP
138 PASSIVATION FILM
140 CHIP AREA
141 EFFECTIVE PIXEL REGION
142 PERIPHERAL REGION
150 SCRIBE REGION
601 AIR GAP
1000 ELECTRONIC DEVICE
1020 IMAGING LENS
1030 STORAGE UNIT
1035 MODIFIED/DETERIORATED REGION
1040 PROCESSOR
1341 FILAMENT
L1 LIGHT
L2 LASER LIGHT
LD PIXEL DRIVE LINE
LD111 TRANSFER TRANSISTOR DRIVE LINE
LD112 RESET TRANSISTOR DRIVE LINE
LD114 SELECTION TRANSISTOR DRIVE LINE
PD PHOTODIODE
VSL VERTICAL SIGNAL LINE

1. A solid-state imaging device comprising:
a semiconductor substrate including a light receiving element in a first region on a first surface;
a glass substrate facing the first surface of the semiconductor substrate;
a resin layer that supports the glass substrate against the first surface; and
a layer provided in the glass substrate, the layer being provided in a third region corresponding to a second region surrounding the first region of the semiconductor substrate in a substrate thickness direction of the semiconductor substrate, the layer having a physical property with respect to visible light different from a physical property of the glass substrate.

2. The solid-state imaging device according to claim 1,
wherein at least one of transmittance, reflectance, or refractive index of the layer with respect to visible light is different from transmittance, reflectance, or refractive index of the glass substrate with respect to visible light.

3. The solid-state imaging device according to claim 1,
wherein the layer is provided in the third region including a region sandwiched between at least one end surface of the end surfaces of the glass substrate, and the first region.

4. The solid-state imaging device according to claim 1,
wherein the layer is closer to an end surface of the glass substrate than to the first region.

5. The solid-state imaging device according to claim 4,
wherein the layer forms a part of the end surface of the glass substrate.

6. The solid-state imaging device according to claim 1,
wherein the semiconductor substrate further includes a light shielding film provided on the second region on the first surface so as to surround the first region, and
the layer is provided at a position corresponding to the light shielding film in the substrate thickness direction.

7. The solid-state imaging device according to claim 1,
wherein the layer includes a plurality of layers arranged hierarchically with respect to an end surface of the glass substrate.

8. The solid-state imaging device according to claim 1,
wherein the layer is inclined with respect to a surface of the glass substrate facing the semiconductor substrate.

9. The solid-state imaging device according to claim 8,
wherein the semiconductor substrate further includes a light shielding film provided on the second region on the first surface so as to surround the first region, and
one of ends of the layer in a direction perpendicular to the first surface is disposed at a position corresponding to the light shielding film in the substrate thickness direction.

10. The solid-state imaging device according to claim 1,
wherein an end of the layer in a direction parallel to the first surface reaches an end surface of the glass substrate.

11. The solid-state imaging device according to claim 1,
wherein an end of the layer in a direction parallel to the first surface is separated from an end surface of the glass substrate.

12. The solid-state imaging device according to claim 1,
wherein the layer reaches a second surface of the glass substrate facing the semiconductor substrate from a third surface opposite to the second surface of the glass substrate.

13. The solid-state imaging device according to claim 1,
wherein an end of the layer in a direction perpendicular to the first surface, the end being an end on the semiconductor substrate side, is separated from a second surface of the glass substrate facing the semiconductor substrate.

14. The solid-state imaging device according to claim 1,
wherein an end of the layer in a direction perpendicular to the first surface, the end being an end on the semiconductor substrate side, reaches the resin layer.

15. The solid-state imaging device according to claim 1,
wherein the layer is a filament formed by modifying a part of the glass substrate.

16. The solid-state imaging device according to claim 1,
wherein the layer is an ion implantation region formed by implanting a dopant into a part of the glass substrate.

17. The solid-state imaging device according to claim 1,
wherein the resin layer covers the first region in the semiconductor substrate.

18. The solid-state imaging device according to claim 1,
wherein an air gap is provided between the first region in the semiconductor substrate and the glass substrate.

19. The solid-state imaging device according to claim 1,
wherein an end surface of the semiconductor substrate and an end surface of the glass substrate are included in an identical plane.

20. An electronic device comprising:
a solid-state imaging device;
an optical system that forms an image based on incident light onto a light receiving surface of the solid-state imaging device; and
a processor that controls the solid-state imaging device,
wherein the solid-state imaging device includes:
a semiconductor substrate including a light receiving element in a first region on a first surface;
a glass substrate facing the first surface of the semiconductor substrate;
a resin layer that supports the glass substrate against the first surface; and
a layer provided in the glass substrate, the layer being provided in a third region corresponding to a second region surrounding the first region of the semiconductor substrate in a substrate thickness direction of the semiconductor substrate, the layer having a physical property with respect to visible light different from a physical property of the glass substrate.
